(19) United States
(12) Patent Application Publication
(10) Pub. No.: US 2026/0275491 A1
(43) Pub. Date: Sep. 17, 2026

(54) YTTRIUM-CONTAINING PROTECTIVE FILM, METHOD FOR PRODUCING SAME, AND COMPONENT

(71) Applicants: AGC Inc., Tokyo (JP); TSUBASA SCIENCE CORPORATION, Yokohama-shi (JP)

(72) Inventors: Koji KAWAHARA, Tokyo (JP); Naoto KIHARA, Tokyo (JP); Kotaro ISHITA, Tokyo (JP); Tomonori OGAWA, Tokyo (JP); Shuhei OGAWA, Tokyo (JP); Michio ISHIKAWA, Kanagawa (JP); Michio TANIMURA, Kanagawa (JP); Hidekazu OKADA, Kanagawa (JP)

(73) Assignees: AGC Inc., Tokyo (JP); TSUBASA SCIENCE CORPORATION, Yokohama-shi (JP)

(21) Appl. No.: 19/649,260

(22) Filed: Apr. 16, 2026

Related U.S. Application Data
(63) Continuation of application No. PCT/JP2024/037378, filed on Oct. 21, 2024.

(30) Foreign Application Priority Data
Oct. 26, 2023 (JP) 2023-183998

(51) Int. Cl. C23C 14/08; C23C 14/22

(52) U.S. Cl. CPC C23C 14/083; C23C 14/221

(57) ABSTRACT

An yttrium-based protective film includes 0.10 atom % to 3.00 atom % of argon. A method for producing the yttrium-based protective film includes evaporating an evaporation source and depositing the evaporation source onto a substrate while irradiating with ions of at least one element selected from the group consisting of oxygen, argon, neon, krypton, and xenon from an ion gun in a vacuum, and Y₂O₃ or a combination of Y₂O₃ and YF₃ is used as the evaporation source.

### CROSS-REFERENCE TO RELATED APPLICATIONS

This is a bypass continuation of International Application No. PCT/JP2024/037378 filed on Oct. 21, 2024, and claims priority from Japanese Patent Application No. 2023-183998 filed on Oct. 26, 2023, the entire content of which is incorporated herein by reference.

### TECHNICAL FIELD

The present invention relates to an yttrium-based protective film, a method for producing the yttrium-based protective film, and a member.

### BACKGROUND ART

When a semiconductor device is produced, for example, a surface of a semiconductor substrate (silicon wafer) is microfabricated by dry etching using halogen-based gas plasmas in a chamber, and the chamber from which the semiconductor substrate is taken out after the dry etching is cleaned using oxygen gas plasmas.

At this time, the member exposed to the plasma in the chamber may corrode, and portions of the corroded member may detach as particles. The detached particles adhere to the semiconductor substrate and may become foreign matter that causes circuit defects.

In the related art, a protective film (yttrium-based protective film) containing yttrium oxides or yttrium oxyfluorides has been known as a protective film for protecting the member exposed to plasmas.

Patent Literature 1 discloses a thermal sprayed coating that is formed by thermal spraying and contains yttrium oxides or yttrium oxyfluorides.
Patent Literature 1: JP2018-76546A

### SUMMARY OF INVENTION

The yttrium-based protective film is generally used in a plasma environment while disposed on a surface of a substrate. The “surface of a substrate” includes surfaces of various layers (such as a base layer) disposed on the surface of the substrate (the same applies hereinafter).

In the plasma environment, it is unlikely that stress large enough to cause the yttrium-based protective film to peel off from the surface of the substrate occurs in the yttrium-based protective film.

Therefore, it is sufficient that an average value of adhesion strength of the yttrium-based protective film to the surface of the substrate (hereinafter, simply referred to as “adhesion strength”) is at least a certain value.

However, even if the average value of the adhesion strength of the yttrium-based protective film is at least a certain value, adhesion strength may have a large variation.

In this case, since the yttrium-based protective film has a portion where the adhesion strength is much lower than the average value, events such as generation of particles are likely to occur in that portion.

Therefore, from the viewpoint of quality control, the yttrium-based protective film is required to have a small variation in adhesion strength.

The present invention has been made in view of the above points, and an object thereof is to provide an yttrium-based protective film having a small variation in adhesion strength.

As a result of intensive studies, the present inventors have found that the above objective can be achieved by adopting the following configuration, and have completed the present invention.

That is, the present invention provides the following [1] to [24].

[1] An yttrium-based protective film including 0.10 atom % to 3.00 atom % of argon.

[2] The yttrium-based protective film according to [1], having a porosity of less than 0.5 volume %.

[3] The yttrium-based protective film according to [1] or [2], having a Vickers hardness of 1000 HV or more.

[4] The yttrium-based protective film according to any one of [1] to [3], having a Vickers hardness of 1300 HV or more.

[5] The yttrium-based protective film according to any one of [1] to [4], having a thickness of 0.05 μm or more and 15.0 μm or less.

[6] The yttrium-based protective film according to any one of [1] to [5], having a crystallite size of 6 nm or more and 40 nm or less.

[7] The yttrium-based protective film according to any one of [1] to [6], including 5 atom % or more of yttrium.

[8] The yttrium-based protective film according to any one of [1] to [7], in which an O/Y ratio, which is a ratio of an oxygen content to an yttrium content, is 1.10 or more and 1.40 or less,
in which units of the oxygen content and the yttrium content are both atom %.

[9] The yttrium-based protective film according to any one of [1] to [8], including an yttrium oxide.

[10] The yttrium-based protective film according to [9], in which a degree of orientation of a (222) plane of Y₂O₃ is 50% or more.

[11] The yttrium-based protective film according to any one of [1] to [10], in which a peak intensity ratio of Y₅O₄F₇ in an X-ray diffraction pattern is 60% or more.

[12] The yttrium-based protective film according to any one of [1] to [11], having the number of hydrogen atoms of 5.0×10²¹ atoms/cm³ or less.

[13] The yttrium-based protective film according to any one of [1] to [12], having a compressive stress of 100 MPa to 1700 MPa.

[14]A member including a substrate and the yttrium-based protective film according to any one of [1] to [13] in this order.

[15] The member according to [14],
in which the substrate is made of at least one selected from the group consisting of carbon, ceramic, and metal,
the ceramic is at least one selected from the group consisting of glass, quartz, aluminum oxide, aluminum nitride, cordierite, yttrium oxide, silicon carbide, Si-impregnated silicon carbide, silicon nitride, sialon, and aluminum oxynitride, and
the metal is at least one selected from the group consisting of aluminum and an alloy including aluminum.

[16] The member according to [14] or [15], in which the substrate is made of quartz or aluminum oxide.

[17] The member according to any one of [14] to [16], in which a surface roughness of a deposition surface of the substrate is, in terms of an arithmetic average roughness Ra, 0.001 μm or more and less than 1.0 μm.

[18] The member according to any one of [14] to [17], including one or more base layers between the substrate and the yttrium-based protective film,
in which the base layer includes at least one oxide selected from the group consisting of Al₂O₃, SiO₂, Y₂O₃, MgO, ZrO₂, La₂O₃, Nd₂O₃, Yb₂O₃, Eu₂O₃, and Gd₂O₃.

[19] The member according to [18], including two or more base layers,
in which the oxides in the adjacent base layers are different from each other.

[20] The member according to any one of [14] to [19],
in which a maximum length of a deposition surface of the substrate is 30 mm or more,
the substrate includes, as the deposition surface, a first deposition surface defining the maximum length and a second deposition surface different from the first deposition surface,
an angle formed between the first deposition surface and the second deposition surface is 20° to 150°, and
a proportion of an area of the second deposition surface to the total area of the deposition surface is 60% or less.

[21] The member according to any one of [14] to [20], which is used in a plasma etching apparatus or a plasma CVD apparatus.

[22]A method for producing the yttrium-based protective film according to any one of [1] to [13], the method including evaporating an evaporation source and depositing the evaporation source onto a substrate while irradiating with ions of at least one element selected from the group consisting of oxygen, argon, neon, krypton, and xenon from an ion gun in a vacuum,
in which Y₂O₃ or a combination of Y₂O₃ and YF₃ is used as the evaporation source.

[23] The method for producing the yttrium-based protective film according to [22],
in which argon ions and oxygen ions are irradiated from the ion gun toward the substrate, and
an Ar/O ratio, which is a ratio of an ion amount of argon to an ion amount of oxygen, is more than 2/50,
in which a unit of the ion amount is W/m²

[24] The method for producing an yttrium-based protective film according to [22] or [23], including heating the substrate at 300° C. or higher before depositing the evaporation source onto the substrate.

According to the present invention, an yttrium-based protective film having a small variation in adhesion strength can be provided.

### BRIEF DESCRIPTION OF DRAWINGS

FIG. 1 is a schematic diagram illustrating an example of a member.

FIG. 2 is a schematic diagram illustrating a ring-shaped substrate with a half cut away.

FIG. 3 is a schematic diagram illustrating a part of a cross section of another ring-shaped substrate.

FIG. 4 is a schematic diagram illustrating a part of a cross section of still another ring-shaped substrate.

FIG. 5 is a schematic diagram illustrating an apparatus used for producing an yttrium-based protective film.

### DESCRIPTION OF EMBODIMENTS

The terms used in the present invention have the following meanings.

A numerical range represented by using “to” means a range including numerical values described before and after “to” as a lower limit value and an upper limit value.

### [Yttrium-Based Protective Film]

The yttrium-based protective film according to the present embodiment contains 0.10 atom % to 3.00 atom % of argon. Hereinafter, the yttrium-based protective film according to the present embodiment is described in more detail.

### <Ar Content>

In the present embodiment, the yttrium-based protective film contains a certain amount of argon (Ar). Accordingly, the yttrium-based protective film maintains a certain degree of adhesion strength (average value), and the variation in adhesion strength is reduced. In addition, the Vickers hardness increases.

First, in the present embodiment, the yttrium-based protective film is formed by an ion-assisted deposition (IAD) method. The IAD method is generally a method in which an evaporation source is evaporated and deposited onto a substrate while irradiating with ions in vacuum.

In this case, for example, irradiating with argon (Ar), which has a high kinetic energy, together with oxygen (O) ions increases the strength with which the evaporated evaporation source is injected into the substrate, as compared with the irradiation with only oxygen (O) ions.

Accordingly, it is presumed that the yttrium-based protective film containing Ar is formed, and the formed yttrium-based protective film has a small variation in adhesion strength and a large Vickers hardness while maintaining a certain degree of adhesion strength (average value).

Specifically, for the reason that the variation in the adhesion strength of the yttrium-based protective film is reduced and the Vickers hardness is increased, the content of argon (Ar content) in the yttrium-based protective film is 0.10 atom % or more, preferably 0.20 atom % or more, more preferably 0.30 atom % or more, still more preferably 0.40 atom % or more, particularly preferably 0.60 atom % or more, and most preferably 0.70 atom % or more.

However, when the Ar content in the yttrium-based protective film is too large, the variation in the adhesion strength of the yttrium-based protective film increases, and the Vickers hardness decreases. The average value of the adhesion strength also decreases.

Therefore, the Ar content in the yttrium-based protective film is 3.00 atom % or less, preferably 2.00 atom % or less, more preferably 1.50 atom % or less, still more preferably 1.00 atom % or less, and particularly preferably 0.80 atom % or less.

The method for measuring the Ar content in the yttrium-based protective film is described below.

### <Adhesion Strength>

Next, the adhesion strength of the yttrium-based protective film (the adhesion strength of the yttrium-based protective film to the surface of the substrate) is described.

### <<Average Value of Adhesion Strength>>

The average value of the adhesion strength of the yttrium-based protective film is preferably 3.0 N or more, more preferably 3.5 N or more, still more preferably 4.0 N or more, particularly preferably 4.5 N or more, and most preferably 5.0 N or more.

On the other hand, the average value of the adhesion strength of the yttrium-based protective film is preferably 10.0 N or less, more preferably 8.0 N or less, still more preferably 7.0 N or less, yet still more preferably 6.0 N or less, particularly preferably 5.5 N or less, and most preferably less than 5.5 N.

### <<Standard Deviation of Adhesion Strength>>

A smaller standard deviation of the adhesion strength of the yttrium-based protective film is preferable because the variation can be evaluated to be small.

Specifically, the standard deviation of the adhesion strength of the yttrium-based protective film is preferably 2.0 N or less, more preferably 1.0 N or less, still more preferably 0.7 N or less, yet still more preferably 0.5 N or less, particularly preferably 0.3 N or less, and most preferably 0.2 N or less.

### <<Method for Measuring Adhesion Strength>>

The adhesion strength of the yttrium-based protective film is determined by a scratch test.

In the scratch test, an indenter is brought into close contact with the yttrium-based protective film (sample) disposed on the surface of the substrate, and the indenter is moved at a constant speed with respect to the position-fixed sample while changing a load. Accordingly, a groove (scratch mark) long in one direction is formed in the sample, and chipping gradually begins to form at a widthwise end (short-side direction) of the groove.

The load (unit: N) when the chipping is formed is determined as the adhesion strength.

For each sample, the scratch test is performed three times under the following conditions, and the average value and the standard deviation of the adhesion strength are calculated.

### (Scratch Test Conditions)

Scratch tester: Revetest Scratch Tester 3 (manufactured by Anton Paar)
Indenter: diamond indenter (tip curvature radius: 200 μm)
Load rate: 200 N/min
Scratch speed: 10 mm/min
Temperature: 24° C. to 26° C.
Relative humidity: 32% to 40%

### <Vickers Hardness>

For the reason that the yttrium-based protective film has excellent plasma resistance, the Vickers hardness of the yttrium-based protective film is 800 HV or more, preferably 900 HV or more, more preferably 1000 HV or more, still more preferably 1100 HV or more, and particularly preferably 1300 HV or more.

On the other hand, the Vickers hardness of the yttrium-based protective film is, for example, 1800 HV or less, and preferably 1600 HV or less.

In order to adjust the Vickers hardness within the above range, it is preferable to produce the yttrium-based protective film by the production method described below.

The Vickers hardness of the yttrium-based protective film is measured using a nanoindentation tester (iMicro, manufactured by KLA). More specifically, the nanoindentation hardness is measured by changing the load within 0 mN to 50 mN. The measurement is performed at 20 locations, and an average value thereof is converted into Vickers hardness using a conversion formula (relational expression) described in ISO14577-1 Annex F.

Other test conditions are as follows.

As a nanoindentation tester, “iMicro” manufactured by KLA is used, and a sample (yttrium-based protective film disposed on the surface of the substrate) is fixed to a sample stage.

A thermoplastic temporary adhesive “crystal bond 555” (fluidization temperature: 48° C.) manufactured by Aremco is used for fixing the sample.

As an actuator, “inForce50” that can be used with a load up to 50 mN is selected.

As the indenter, a Berkovich indenter (tip curvature radius: 20 nm) having a triangular pyramidal tip is used.

### <Porosity>

For the reason that the plasma resistance of the yttrium-based protective film is excellent, the porosity of the yttrium-based protective film is preferably less than 0.5 volume %, more preferably 0.3 volume % or less, still more preferably 0.2 volume % or less, and particularly preferably 0.1 volume % or less.

In order to adjust the porosity within the above range, it is preferable to produce the yttrium-based protective film by the production method described below.

The porosity of the yttrium-based protective film is determined as follows.

First, using a focused ion beam (FIB), slope processing is performed on a part of the yttrium-based protective film and the substrate described below in a thickness direction at an angle of 52° from the surface of the yttrium-based protective film toward the substrate, thereby exposing a cross section. The exposed cross section is observed at a magnification of 20000 times using a field emission scanning electron microscope (FE-SEM), and a cross-sectional image thereof is captured.

The cross-sectional image is captured at a plurality of locations. Specifically, for example, when the yttrium-based protective film is circular, images are captured at five points in total: one point at a center of the surface of the yttrium-based protective film and four points at positions that are 10 mm inward from the outer periphery, and the size of the cross-sectional image is 6 μm×5 μm. When the thickness of the yttrium-based protective film is 5 μm or more, cross-sectional images are respectively captured at a plurality of imaging locations so that the entire cross section of the yttrium-based protective film can be observed in the thickness direction.

Subsequently, the area of the pore portion in the cross-sectional image is determined by analyzing the obtained cross-sectional image using image analysis software (ImageJ, provided by National Institute of Health). The proportion of the area of the pore portion to the area of the entire cross section of the yttrium-based protective film is calculated and regarded as the porosity (unit: volume %) of the yttrium-based protective film. Regarding pores that are too fine to be detected by the image analysis software (pores with a pore diameter of 20 nm or less), areas thereof are regarded as 0.

### <Composition>

In the present embodiment, the yttrium content in the yttrium-based protective film is preferably 5 atom % or more, more preferably 10 atom % or more, and still more preferably 20 atom % or more for the reason that the yttrium-based protective film has excellent plasma resistance. From the viewpoint of enhancing the electrical insulation, the yttrium content in the yttrium-based protective film is preferably 70 atom % or less, more preferably 60 atom % or less, and still more preferably 50 atom % or less.

In the present embodiment, the yttrium-based protective film preferably contains, for example, yttrium oxides or yttrium oxyfluorides.

### <<O/Y Ratio>>

When the yttrium-based protective film contains yttrium oxides or yttrium oxyfluorides, the yttrium-based protective film contains at least yttrium (Y) and oxygen (O).

For the reason that the plasma resistance of the yttrium-based protective film is excellent, an amount of Y is preferably relatively large, and specifically, the O/Y ratio of the yttrium-based protective film is preferably 1.40 or less, more preferably 1.30 or less, and still more preferably 1.20 or less.

On the other hand, when the yttrium-based protective film contains yttrium oxyfluorides, the O/Y ratio of the yttrium-based protective film is preferably 0.70 or more, more preferably 0.75 or more, and still more preferably 0.80 or more.

When the yttrium-based protective film contains yttrium oxide, the O/Y ratio of the yttrium-based protective film is preferably 0.90 or more, more preferably 1.00 or more, and still more preferably 1.10 or more.

The O/Y ratio is a ratio of a content of 0 (unit: atom %) to a content of Y (unit: atom %) in the yttrium-based protective film.

Hereinafter, each of the cases where the yttrium-based protective film contains yttrium oxides or yttrium oxyfluorides is described.

### <<Yttrium Oxides>>

First, a case where the yttrium-based protective film contains yttrium oxide (Y₂O₃) is described.

In this case, the Y₂O₃ content in the yttrium-based protective film is preferably 95 mass % or more, and more preferably 98 mass % or more.

The Y₂O₃ content in the yttrium-based protective film produced using only Y₂O₃ as the evaporation source by the production method described below satisfies the above range.

### (Degree of Orientation)

When increasing the area of the yttrium-based protective film, from the viewpoint of preventing the occurrence of cracks (including wrinkles; the same applies below) in the yttrium-based protective film, a higher degree of orientation of the (222) plane of Y₂O₃ in the yttrium-based protective film (hereinafter, also simply referred to as “degree of orientation”) is preferable.

Therefore, the degree of orientation of the yttrium-based protective film is preferably 50% or more, more preferably 65% or more, still more preferably 80% or more, yet still more preferably 85% or more, particularly preferably 90% or more, more particularly preferably 95% or more, even more preferably 98% or more, and most preferably 99% or more.

In order to adjust the degree of orientation within the above range, it is preferable to produce the yttrium-based protective film by the production method described below.

The degree of orientation is the proportion (unit: %) of a peak intensity of the (222) plane when the total of the peak intensities of the respective surfaces of Y₂O₃ in the XRD pattern of the yttrium-based protective film is 100.

The XRD pattern of the yttrium-based protective film (and the stress-relaxation layer and the base layer described below) is obtained by performing an XRD measurement in a micro portion 2D (two-dimensional) mode using an X-ray diffractometer (D8 DISCOVER Plus, manufactured by Bruker) under the following conditions.
X-ray source: CuKα ray (output: 45 kV, current: 120 mA)
Scanning range: 2θ=10° to 80°
Step time: 0.2 s/step
Scan speed: 10°/min
Step width: 0.02°
Detector: multi-mode detector EIGER (2D mode)
Incident side optical system: multilayer mirror+1.0 mmφ micro slit+1.0 mmφ collimator
Light receiving side optical system: OPEN

### (Yttrium Oxyfluoride)

Next, a case where the yttrium-based protective film contains yttrium oxyfluorides is described.

Examples of the chemical formula representing yttrium oxyfluorides include YOF and Y₅O₄F₇. YOF is an oblique crystal having a low hardness, whereas Y₅O₄F₇ has a special crystal structure called a rhombohedron and has a high hardness.

In the present embodiment, the yttrium-based protective film preferably has a high proportion of Y₅O₄F₇ having a rhombohedral crystal structure. That is, it is preferable that a peak intensity ratio of Y₅O₄F₇ in the X-ray diffraction pattern is at least a certain value. Accordingly, the yttrium-based protective film is hard and exhibits a Vickers hardness at least a certain value.

### (Peak Intensity Ratio)

The peak intensity ratio of Y₅O₄F₇ in the X-ray diffraction pattern of the yttrium-based protective film (hereinafter, also referred to as “Y₅O₄F₇ peak intensity ratio” or simply “peak intensity ratio”) is 60% or more, preferably 80% or more, more preferably 90% or more, and still more preferably 95% or more.

In order to adjust the Y₅O₄F₇ peak intensity ratio within the above range, it is preferable to produce the yttrium-based protective film by the production method described below.

The Y₅O₄F₇ peak intensity ratio is a proportion (unit: %) of the main peak intensity of Y₅O₄F₇ when the total of the main peak intensities of crystal phases shown below is 100 in the X-ray diffraction (XRD) pattern of the yttrium-based protective film.

As for the main peak of each crystal phase, the main peak of Y₅O₄F₇ appears in the vicinity of 2θ=28.1°, the main peak of Y₂O₃ appears in the vicinity of 2θ=29.2°, and the main peak of YOF appears in the vicinity of 2θ=29.2°.

At the main peak position of Y₅O₄F₇, the peak of Y₆O₅F₈ crystal and the peak of Y₇O₆F₉ crystal overlap. Furthermore, the main peak of YF₃ also overlaps the main peak position of Y₅O₄F₇.

The peaks at the main peak position of Y₅O₄F₇ are all treated as peaks of Y₅O₄F₇. When the YF₃ crystal is present, the peak intensity in the vicinity of 2θ=24.5°, which is the second main peak of the YF₃ crystal, is multiplied by 1.3 and converted to an equivalent main peak intensity, and this peak intensity is defined as the main peak intensity of YF₃. At this time, the intensity of the second main peak of the YF₃ crystal converted by being multiplied by 1.3 is subtracted from the intensity of the peak of Y₅O₄F₇ (peaks located at the main peak position of Y₅O₄F₇). If the intensity (relative intensity) of the second main peak of the YF₃ crystal is “2.0” and the intensity (relative intensity) of the peak at the main peak position of Y₅O₄F₇ is “6.0”, the intensity of the second main peak of the YF₃ crystal is converted into “2.6” (=2.0×1.3). Therefore, the intensity of the peak at the main peak position of Y₅O₄F₇ is reduced by the converted intensity of the second main peak of the YF₃ crystal to obtain “3.4” (=6.0-2.6).

The XRD pattern of the yttrium-based protective film is obtained by performing an XRD measurement in a micro portion 2D (two-dimensional) mode using an X-ray diffractometer (D8 DISCOVER Plus, manufactured by Bruker) under the above-described conditions.

### (Content of Each Element)

The yttrium-based protective film contains yttrium (Y), oxygen (O), and fluorine (F) when the yttrium-based protective film contains yttrium oxyfluorides.

Here, the Y content in the yttrium-based protective film is preferably 20 atom % or more, more preferably 25 atom % or more, still more preferably 26 atom % or more, particularly preferably 27 atom % or more, and most preferably 27.5 atom % or more.

On the other hand, the Y content in the yttrium-based protective film is preferably 35 atom % or less, more preferably 30 atom % or less, still more preferably 29 atom % or less, and particularly preferably 28 atom % or less.

The O content in the yttrium-based protective film is preferably 20 atom % or more, more preferably 21 atom % or more, still more preferably 22 atom % or more, particularly preferably 23 atom % or more, and most preferably 24 atom % or more.

On the other hand, the O content in the yttrium-based protective film is preferably 35 atom % or less, more preferably 30 atom % or less, still more preferably 28 atom % or less, particularly preferably 26 atom % or less, and most preferably 25 atom % or less.

The F content in the yttrium-based protective film is preferably 35 atom % or more, more preferably 40 atom % or more, still more preferably 44 atom % or more, particularly preferably 47 atom % or more, and most preferably 48 atom % or more.

On the other hand, the F content in the yttrium-based protective film is preferably 60 atom % or less, more preferably 55 atom % or less, still more preferably 52 atom % or less, yet still more preferably 50 atom % or less, particularly preferably 49.5 atom % or less, and most preferably 49 atom % or less.

In order to adjust the content of each element within the above range, for example, in the production method described below, production conditions such as the amount of the evaporation source are appropriately adjusted.

The content (unit: atom %) of each element in the yttrium-based protective film is measured using an energy dispersive X-ray spectrometer (EX-250SE, manufactured by Horiba, Ltd.).

### <Crystallite Size>

As described above, for example, the particles detached from the member exposed to the plasma may adhere to a semiconductor substrate and become a foreign matter causing circuit defects.

At this time, as the sizes of the particles are reduced, the occurrence of defects can be prevented.

Therefore, the crystallite size of the yttrium-based protective film is preferably 40 nm or less, more preferably 30 nm or less, still more preferably 20 nm or less, and particularly preferably 15 nm or less.

On the other hand, as the crystallite size of the yttrium-based protective film increases, the change in the crystallite size when heated is small and stable, and the heat resistance is improved.

Therefore, the crystallite size of the yttrium-based protective film is preferably 6 nm or more, more preferably 7 nm or more, and still more preferably 10 nm or more.

That is, the yttrium-based protective film preferably has a crystallite size of 6 nm or more and 40 nm or less.

In order to adjust the crystallite size within the above range, it is preferable to produce the yttrium-based protective film by the production method described below.

The crystallite size of the yttrium-based protective film is determined using Scherrer's formula based on data of XRD pattern data obtained by the XRD measurement of the mirror-polished yttrium-based protective film.

### <Thickness>

The thickness of the yttrium-based protective film is, for example, 0.05 μm or more, and for the reason that the variation in adhesion strength is further reduced, it is preferably 0.1 μm or more, more preferably 0.3 μm or more, still more preferably 0.8 μm or more, particularly preferably 2.0 μm or more, and most preferably 4.0 μm or more.

On the other hand, the thickness of the yttrium-based protective film is preferably 100.0 μm or less, more preferably 50.0 μm or less, still more preferably 30.0 μm or less, yet still more preferably 15.0 μm or less, and particularly preferably 12.0 μm or less.

That is, the yttrium-based protective film preferably has a thickness of 0.05 μm or more and 15.0 μm or less.

The thickness of the yttrium-based protective film is measured as follows.

The cross section of the yttrium-based protective film is observed using a scanning electron microscope (SEM), the thickness of the yttrium-based protective film is measured at any five points, and an average value of the thickness of the measured five points is regarded as the thickness (unit: m) of the yttrium-based protective film.

### <Number of Hydrogen Atoms>

The number of hydrogen atoms in the yttrium-based protective film is preferably small. Accordingly, the plasma resistance of the yttrium-based protective film is excellent.

The reasons for this are presumed to be as follows. That is, when the amount of hydrogen in the yttrium-based protective film is large, the hydrogen easily reacts with fluorine contained in the plasma (or the gas used to generate the plasma), and as a result, the yttrium-based protective film is likely to be damaged. On the other hand, when the amount of hydrogen in the yttrium-based protective film is small, the reaction with fluorine is relatively reduced, and damage to the yttrium-based protective film is reduced.

Specifically, the number of hydrogen atoms in the yttrium-based protective film is preferably 5.0×10²¹ atoms/cm³ or less, more preferably 4.5×10²¹ atoms/cm³ or less, still more preferably 3.5×10²¹ atoms/cm³ or less, yet still more preferably 3.0×10²¹ atoms/cm³ or less, particularly preferably 2.5×10²¹ atoms/cm³ or less, and most preferably 2.3×10²¹ atoms/cm³ or less.

Hydrogen in the yttrium-based protective film is highly likely due to the moisture contained in the substrate described below. In particular, when the material of the substrate is ceramic, the number of hydrogen atoms in the yttrium-based protective film to be formed can be reduced by heating (preheating) the substrate before forming the yttrium-based protective film.

On the other hand, the number of hydrogen atoms in the yttrium-based protective film is preferably 0.1×10²¹ atoms/cm³ or more, and more preferably 0.5×10²¹ atoms/cm³ or more.

The number of hydrogen atoms in the yttrium-based protective film is determined using a secondary ion mass spectrometer (model IMS-6f, manufactured by AMETEK, Inc.) under the conditions of primary ion species Cs⁺, a primary acceleration voltage of 15.0 kV, and a detection region of φ 8 μm and a measurement depth of 500 nm.

### <Compressive Stress>

The stress (internal stress, residual stress) of the yttrium-based protective film is preferably not a tensile stress but a compressive stress.

The compressive stress of the yttrium-based protective film is preferably 100 MPa or more, more preferably 300 MPa or more, still more preferably 500 MPa or more, and particularly preferably 700 MPa or more.

On the other hand, the compressive stress of the yttrium-based protective film is preferably 1700 MPa or less, more preferably 1600 MPa or less, and still more preferably 1500 MPa or less.

That is, the compressive stress of the yttrium-based protective film is preferably 100 MPa to 1700 MPa.

The compressive stress of the yttrium-based protective film is determined as follows.

An yttrium-based protective film is formed on a quartz glass substrate, a surface shape of the formed yttrium-based protective film is measured using a surface shape measurement apparatus (SURFCOM NEX 241 SD2-13, manufactured by Tokyo Seimitsu Co., Ltd.), and the compressive stress (film stress σ) of the yttrium-based protective film is determined based on the Stoney's equation (the following equation).

$$σ = {Yd}^{2} / ( 6 c ( 1 - v ) t )$$

In the above equation, σ: film stress, Y: Young's modulus of substrate, d: thickness of substrate, v: Poisson's ratio of substrate, t: thickness of yttrium-based protective film, and c: radius of curvature.

### [Member]

Next, the member according to the present embodiment is described.

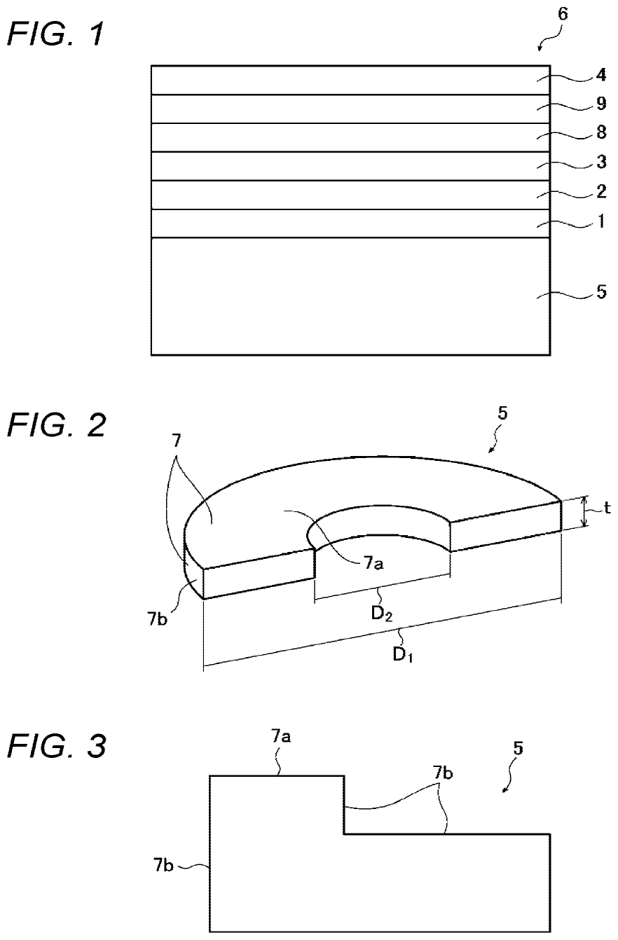

First, the member according to the present embodiment is schematically described with reference to FIG. 1.

FIG. 1 is a schematic diagram illustrating an example of a member 6.

The member 6 includes at least a substrate 5 and an yttrium-based protective film 4 in this order.

In the present embodiment, the yttrium-based protective film according to the present embodiment described above is used as the yttrium-based protective film 4.

As illustrated in FIG. 1, base layers (a base layer 1, a base layer 2, and a base layer 3) and stress-relaxation layers (a stress-relaxation layer 8 and a stress-relaxation layer 9) may be disposed between the substrate 5 and the yttrium-based protective film 4.

The number of the base layers is not limited to three. In addition, the number of the stress-relaxation layers is not limited to two.

Hereinafter, each part of the member according to the present embodiment is described in detail.

### <Substrate>

The substrate has at least a surface on which an yttrium-based protective film (or a base layer) is formed. Hereinafter, this surface may be referred to as a “deposition surface” for convenience.

### <<Material>>

The material of the substrate is appropriately selected depending on the use of the member or the like.

The substrate is formed of, for example, at least one selected from the group consisting of carbon (C), ceramic, and metal.

Here, the ceramic is, for example, at least one selected from the group consisting of a glass (soda lime glass or the like), quartz, aluminum oxide (Al₂O₃), aluminum nitride (AlN), cordierite, yttrium oxide, silicon carbide (SiC), Si-impregnated silicon carbide, silicon nitride (SiN), sialon, and aluminum oxynitride (AlON). As the ceramic, aluminum oxide or quartz is more preferable.

The Si-impregnated silicon carbide is obtained by heating and melting elemental Si and impregnating silicon carbide (SiC) with the molten Si.

The metal is, for example, at least one selected from the group consisting of aluminum (Al) and an alloy containing aluminum (Al).

### <<Shape>>

The shape of the substrate is not particularly limited, and examples thereof include a flat plate shape, a ring shape, a dome shape, a protruding shape, and a recessed shape. The shape of the substrate is appropriately selected depending on the use of the member.

### <<Surface Roughness of Deposition Surface>>

As the surface roughness of the deposition surface of the substrate is reduced, the degree of orientation of the yttrium-based protective film formed on the deposition surface is likely to increase.

Therefore, the surface roughness of the deposition surface of the substrate is, in terms of the arithmetic average roughness Ra, preferably less than 1.00 μm, more preferably 0.60 μm or less, still more preferably 0.40 μm or less, particularly preferably 0.20 μm or less, and most preferably 0.08 μm or less.

On the other hand, the surface roughness of the deposition surface of the substrate is preferably 0.001 μm or more, more preferably 0.01 μm or more, and still more preferably 0.08 μm or more as the arithmetic average roughness Ra.

The surface roughness (arithmetic average roughness Ra) of the deposition surface is measured in accordance with JIS B 0601: 2001.

### <<Maximum Length of Deposition Surface>>

The maximum length of the deposition surface of the substrate is preferably 30 mm or more, more preferably 70 mm or more, still more preferably 100 mm or more, and particularly preferably 150 mm or more.

The term “maximum length” means the maximum length that the deposition surface has. Specifically, for example, when the deposition surface is circular in plan view, the maximum length is the diameter of the circle. When the deposition surface is a ring in plan view, the maximum length is the outer diameter thereof. When the deposition surface is a rectangle in plan view, the maximum length is the length of the maximum diagonal line.

On the other hand, the maximum length of the deposition surface is, for example, 2000 mm or less, preferably 1500 mm or less, more preferably 1000 mm or less, still more preferably 700 mm or less, and most preferably 500 mm or less.

FIG. 2 is a schematic diagram illustrating a ring-shaped substrate 5 with a half cut away.

For example, when the substrate 5 illustrated in FIG. 2 has an outer diameter D₁ of 100 mm, an inner diameter D₂ of 90 mm, and a thickness t of 5 mm, the maximum length of the substrate 5 is 100 mm.

The substrate 5 has a deposition surface 7, and as illustrated in FIG. 2, the deposition surface 7 may have a first deposition surface 7a defining the maximum length (outer diameter D₁) and a second deposition surface 7b different from the first deposition surface 7a.

The proportion of the area of the second deposition surface 7b to the total area of the deposition surface 7 is, for example, 60% or less.

FIG. 3 is a schematic diagram illustrating a part of a cross section of another ring-shaped substrate 5.

As illustrated in FIG. 3, the substrate 5 may have a plurality of second deposition surfaces 7b.

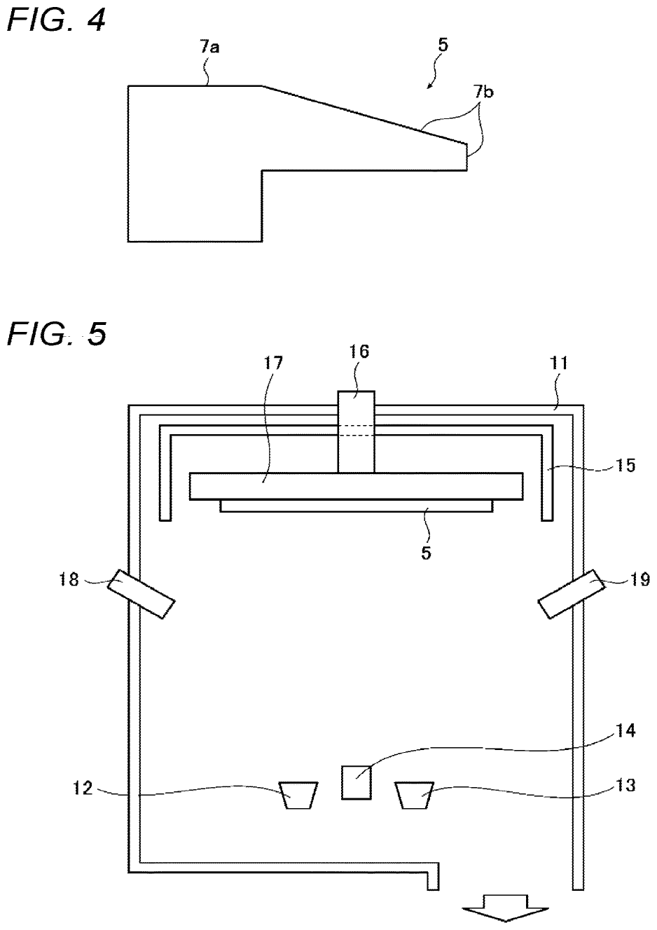

FIG. 4 is a schematic diagram illustrating a part of a cross section of still another ring-shaped substrate 5.

An angle formed between the first deposition surface 7a and the second deposition surface 7b is, for example, 20° to 150°. In the substrate 5 illustrated in FIG. 4, an angle formed by the first deposition surface 7a and the second deposition surface 7b connected to the first deposition surface 7a is about 30°.

### <Stress-Relaxation Layer>

As described above, the base layers and the stress-relaxation layers may be disposed between the substrate and the yttrium-based protective film.

First, among the base layers and the stress-relaxation layers, the stress-relaxation layer disposed at a position closer to the yttrium-based protective film is described.

When at least one stress-relaxation layer is disposed between the substrate and the yttrium-based protective film, the stress (tensile stress) of the yttrium-based protective film is relaxed.

### <<Number of Layers>>

The upper limit of the number of the stress-relaxation layers is not particularly limited, and the number of the base layers is preferably 5 or less, more preferably 4 or less, still more preferably 3 or less, particularly preferably 2 or less, and most preferably 1.

### <<Composition>>

The stress-relaxation layer preferably contains, for example, at least one oxide selected from the group consisting of Al₂O₃ (including “β-Al₂O₃”, the same applies hereinafter), SiO₂, Y₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃ (referred to as “group G” for convenience).

The stress-relaxation layer preferably contains at least two oxides selected from the group G.

The group G preferably consists of Al₂O₃, SiO₂, Y₂O₃, MgO, CaO, SrO, B₂O₃, and ZrO₂, more preferably consists of Al₂O₃, SiO₂, Y₂O₃, MgO, CaO, SrO, and B₂O₃, and still more preferably consists of Al₂O₃, SiO₂, and Y₂O₃.

When the stress-relaxation layer contains only one oxide (for example, Al₂O₃), the content of the oxide (for example, Al₂O₃) in the stress-relaxation layer is preferably 100 mol %.

For example, when the material of the substrate is aluminum nitride (AlN), the stress-relaxation layer in contact with the substrate preferably contains only one oxide (for example, Al₂O₃, MgO, or ZrO₂).

The Al₂O₃ content in the stress-relaxation layer is, for example, 0 mol % or more, preferably 5 mol % or more, more preferably 10 mol % or more, still more preferably 15 mol % or more, yet still more preferably 20 mol % or more, particularly preferably 25 mol % or more, and most preferably 30 mol % or more.

On the other hand, the Al₂O₃ content in the stress-relaxation layer is, for example, 70 mol % or less, preferably 60 mol % or less, more preferably 50 mol % or less, still more preferably 45 mol % or less, particularly preferably 40 mol % or less, and most preferably 35 mol % or less.

The SiO₂ content in the stress-relaxation layer is, for example, 0 mol % or more, preferably 20 mol % or more, more preferably 30 mol % or more, still more preferably 40 mol % or more, particularly preferably 45 mol % or more, and most preferably 50 mol % or more.

On the other hand, the SiO₂ content in the stress-relaxation layer is, for example, 90 mol % or less, preferably 85 mol % or less, more preferably 80 mol % or less, still more preferably 75 mol % or less, yet still more preferably 70 mol % or less, particularly preferably 65 mol % or less, even still more preferably 60 mol % or less, and most preferably 55 mol % or less.

The Y₂O₃ content in the stress-relaxation layer is, for example, 0 mol % or more, preferably 5 mol % or more, more preferably 10 mol % or more, still more preferably 13 mol % or more, particularly preferably 16 mol % or more, and most preferably 19 mol % or more.

On the other hand, the Y₂O₃ content in the stress-relaxation layer is, for example, 60 mol % or less, preferably 40 mol % or less, more preferably 30 mol % or less, still more preferably 25 mol % or less, and most preferably 20 mol % or less.

When the stress-relaxation layer contains Al₂O₃, SiO₂, and Y₂O₃, the content of oxides other than Al₂O₃, SiO₂, and Y₂O₃ (for example, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃) in the stress-relaxation layer is, for example, 20 mol % or less, preferably 10 mol % or less, more preferably 5 mol % or less, still more preferably 1 mol % or less, and most preferably 0 mol %.

When the stress-relaxation layer contains SiO₂ and Y₂O₃, the molar ratio of SiO₂ to Y₂O₃(SiO₂/Y₂O₃) is preferably 90/10 to 20/80, more preferably 80/20 to 30/70, and still more preferably 70/30 to 40/60.

At this time, the content of oxides other than SiO₂ and Y₂O₃ (for example, Al₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃) is preferably 10 mol % or less, more preferably 5 mol % or less, still more preferably 1 mol % or less, and particularly preferably 0 mol %.

The content (unit: mot %) of each oxide in the stress-relaxation layer is measured using an energy dispersive X-ray spectrometer (EX-250SE, manufactured by Horiba, Ltd.).

For example, when the molar ratio of Y, Al, and Si (Y/Al/Si) is 25/25/50, and no element other than Y, Al, Si, and O is detected, the Y₂O₃ content is 25 mol %, the Al₂O₃ content is 25 mol %, and the SiO₂ content is 50 mol %.

The same applies to the base layer described below.

### <<State of Layer>>

The stress-relaxation layer is preferably an amorphous layer.

However, the stress-relaxation layer, which is an amorphous layer, may contain crystals.

### <<Thickness>>

The thickness of each stress-relaxation layer is preferably 0.05 μm or more, more preferably 0.5 μm or more, still more preferably 0.8 μm or more, yet still more preferably 1.1 μm or more, particularly preferably 1.4 μm or more, even still more preferably 1.7 μm or more, and most preferably 2.0 μm or more.

On the other hand, the thickness of each stress-relaxation layer is preferably 9.0 μm or less, more preferably 7.0 μm or less, still more preferably 5.0 μm or less, and particularly preferably 3.0 μm or less.

The thickness of the stress-relaxation layer is measured in the same manner as the thickness of the yttrium-based protective film.

### <Base Layer>

As described above, at least one base layer may be disposed between the substrate and the stress-relaxation layer.

By forming the base layer, the tensile stress of the yttrium-based protective film is relaxed to generate the compressive stress, or the adhesion of the yttrium-based protective film to the substrate is increased.

Among the plurality of layers constituting the stress-relaxation layer, one layer or two or more layers on a substrate side may be regarded as the base layer.

That is, the base layer may be a layer different from the stress-relaxation layer, or may be at least a part of the stress-relaxation layer.

### <<Number of Layers>>

The upper limit of the number of the base layers is not particularly limited, and the number of the base layers is preferably 5 or less, more preferably 4 or less, still more preferably 3 or less, particularly preferably 2 or less, and most preferably 1.

### <<State of Layer>>

The base layer is preferably an amorphous layer or a microcrystalline layer (amorphous layer containing crystals).

### <<Composition>>

When the base layer is at least one layer of the stress-relaxation layer, the composition of the base layer is preferably the same as that described above for the stress-relaxation layer.

On the other hand, when the base layer is a layer different from the stress-relaxation layer, the base layer preferably contains at least one oxide selected from the group consisting of Al₂O₃, SiO₂, Y₂O₃, MgO, ZrO₂, La₂O₃, Nd₂O₃, Yb₂O₃, Eu₂O₃, and Gd₂O₃.

The base layer more preferably contains SiO₂, or includes at least two oxides selected from the group consisting of Al₂O₃, SiO₂, and Y₂O₃.

When two or more base layers are disposed between the substrate and the yttrium-based protective film, the oxides of the base layers are preferably different from each other between the adjacent base layers.

Specific examples of the case where the oxides of the adjacent base layers are different from each other include a case where an oxide of a base layer 1 is “SiO₂”, an oxide of a base layer 2 is “Al₂O₃+SiO₂”, and an oxide of a base layer 3 is “Al₂O₃”.

### <<Thickness>>

The thickness of the base layer is preferably 0.05 μm or more, more preferably 0.1 m or more, still more preferably 0.2 μm or more, yet still more preferably 0.5 μm or more, particularly preferably 0.8 μm or more, and most preferably 1.1 μm or more.

On the other hand, the thickness of the base layer is, for example, 15.0 μm or less, preferably 10.0 μm or less, more preferably 7.0 μm or less, particularly preferably 5.0 μm or less, and most preferably 3.0 μm or less.

The thickness of the base layer is measured in the same manner as the thickness of the yttrium-based protective film.

### <Use of Member>

The member according to the present embodiment is used as, for example, a member such as a top plate in a semiconductor device producing apparatus (a plasma etching apparatus, a plasma CVD apparatus, or the like).

However, the use of the member is not limited thereto.

### [Method for Producing Yttrium-Based Protective Film and Member]

Next, a method of producing the yttrium-based protective film according to the present embodiment is described.

The following description also describes a method of producing the member according to the present embodiment.

In the present embodiment, the ion-assisted deposition (IAD) method is used.

Schematically, an evaporation source (Y₂O₃, YF₃, etc.) is evaporated and deposited onto the substrate while irradiating with ions in a vacuum, thereby forming the yttrium-based protective film.

The yttrium-based protective film can be formed very densely by using the IAD method. That is, the obtained yttrium-based protective film has a low porosity.

In contrast, a large number of pores are likely to remain in the yttrium-based protective film, which is obtained by a method such as a thermal spraying method, an aerosol deposition (AD) method, or an ion plating (IP) method.

### <Apparatus Configuration>

FIG. 5 is a schematic diagram illustrating an apparatus used for producing the yttrium-based protective film.

The apparatus illustrated in FIG. 5 includes a chamber 11. The inside of the chamber 11 can be evacuated to a vacuum by operating a vacuum pump (not illustrated).

Crucibles 12 and 13, and an ion gun 14 are disposed inside the chamber 11, and a holder 17 is disposed above them.

The holder 17 is integrated with a supporting shaft 16 and rotates with the rotation of the supporting shaft 16. A heater 15 is disposed around the holder 17.

The above-described substrate 5 is held by the holder 17 in a state where the deposition surface of the substrate 5 faces downward. The substrate 5 held by the holder 17 rotates with the rotation of the holder 17 while being heated by the heater 15.

Further, quartz crystal film thickness monitors 18 and 19 are attached to the chamber 11.

### <Formation of Yttrium-Based Protective Film (Part 1)>

A case where the yttrium-based protective film (not illustrated in FIG. 5) containing yttrium oxide (Y₂O₃) is formed on the substrate 5 in the apparatus illustrated in FIG. 5 is described.

First, the evaporation source Y₂O₃ is charged into one or both of the crucibles 12 and 13.

After the substrate 5 is held by the holder 17, the inside of the chamber 11 is evacuated to make a vacuum state.

Next, the holder 17 is rotated while driving the heater 15. Accordingly, the substrate 5 is rotated while being heated.

In this state, ion assisted deposition is performed to form a film on the substrate 5.

That is, the evaporation source Y₂O₃ charged in one or both of the crucibles 12 and 13 is evaporated while irradiating with ions (ion beams) from the ion gun 14.

The evaporation source melts and evaporates by being irradiated with electron beams (not illustrated).

In this way, the evaporated evaporation source adheres to the deposition surface of the substrate 5 (or a surface of the base layer or a surface of the stress-relaxation layer when the base layer or the stress-relaxation layer is present), and an yttrium-based protective film containing yttrium oxide (Y₂O₃) is formed.

The ions irradiated from the ion gun 14 are preferably ions of at least one of element selected from the group consisting of oxygen, argon, neon, krypton, and xenon.

As the ions irradiated from the ion gun 14, ions of at least two elements selected from the group consisting of oxygen, argon, neon, krypton, and xenon are more preferably used, and ions of oxygen and argon are more preferably used in combination.

Accordingly, it is presumed that a certain amount of argon (Ar) is included in the yttrium-based protective film to be formed.

### <<Internal Pressure of Chamber>>

The deposition is performed in the vacuum. Specifically, the internal pressure of the chamber 11 is preferably 6×10⁻² Pa or less, more preferably 5×10⁻² Pa or less, and still more preferably 3×10⁻² Pa or less.

On the other hand, the internal pressure of the chamber 11 is preferably more than 1×10⁻⁶ Pa, more preferably 1×10⁻⁵ Pa or more, and still more preferably 1×10⁻⁴ Pa or more.

### <<Temperature of Substrate>>

During the deposition, the temperature of the substrate 5 heated by the heater 15 is preferably 200° C. or higher, more preferably 270° C. or higher, still more preferably 320° C. or higher, particularly preferably 370° C. or higher, and most preferably 400° C. or higher. On the other hand, the temperature is preferably 600° C. or lower, more preferably 500° C. or lower, and still more preferably 450° C. or lower.

### <<Deposition Rate>>

The rates (deposition rate) at which films are formed by evaporating the evaporation sources in the crucibles 12 and 13 are respectively monitored in advance using the quartz crystal film thickness monitors 18 and 19.

The deposition rate is adjusted by controlling conditions of the electron beam irradiated to the evaporation source and conditions (current value, current density, etc.) of the ion beam of the ion gun 14.

During the formation of the yttrium-based protective film, the deposition rate (unit: nm/min) of each evaporation source is adjusted to a desired value.

The deposition rate of the evaporation source Y₂O₃ is preferably 1 nm/min or more, more preferably 1.5 nm/min or more, and still more preferably 2 nm/min or more.

The deposition rate of the evaporation source Y₂O₃ is preferably 20 nm/min or less, more preferably 15 nm/min or less, still more preferably 10 nm/min or less, yet still more preferably 5 nm/min or less, particularly preferably 3.5 nm/min or less, and most preferably 2.1 nm/min or less.

### <<Conditions of Ion Irradiation>>

The distance between the ion gun 14 and the substrate 5 is preferably 700 mm or more, and more preferably 900 mm or more. On the other hand, the distance is preferably 1500 mm or less, and more preferably 1300 mm or less.

The ion beam current value is preferably 1000 mA or more, and more preferably 1500 mA or more. On the other hand, the ion beam current value is preferably 3000 mA or less, and more preferably 2500 mA or less.

The ion beam current density is preferably 40 μA/cm² or more, more preferably 65 μA/cm² or more, still more preferably 75 μA/cm² or more, and particularly preferably 77 μA/cm² or more. On the other hand, the ion beam current density is preferably 140 μA/cm² or less, more preferably 120 μA/cm² or less, and still more preferably 100 μA/cm² or less.

### <<Ar/O Ratio>>

As described above, it is preferable to use argon ions and oxygen ions in combination as the ions irradiated from the ion gun 14.

At this time, the Ar/O ratio, which is a ratio of an amount of argon (Ar) ions to an amount of oxygen (O) ions, is preferably more than 2/50, more preferably 4/50 or more, still more preferably more than 4/50, yet still more preferably 5/50 or more, particularly preferably 6/50 or more, more particularly preferably 7/50 or more, even still more preferably 8/50 or more, and most preferably 10/50 or more.

On the other hand, the Ar/O ratio is 25/50 or less, preferably 20/50 or less, more preferably 15/50 or less, and still more preferably 12/50 or less.

The Ar/O ratio is a ratio of an amount (unit: W/m²) of argon (Ar) ions irradiated from the ion gun 14 toward the substrate 5 to an amount (unit: W/m²) of oxygen (O) ions similarly irradiated from the ion gun 14 toward the substrate 5.

Here, “W/m²” is a unit indicating kinetic energy (ion energy flux) crossing a unit area per unit time.

### <Formation of Yttrium-Based Protective Film (Part 2)>

Next, a case where the yttrium-based protective film (not illustrated in FIG. 5) containing yttrium oxyfluoride is formed on the substrate 5 is described.

First, the evaporation source Y₂O₃ is charged in one crucible 12, and the evaporation source YF₃ is charged in the other crucible 13.

After the substrate 5 is held by the holder 17, the inside of the chamber 11 is evacuated to make a vacuum state.

Next, the holder 17 is rotated while driving the heater 15. Accordingly, the substrate 5 is rotated while being heated.

In this state, ion assisted deposition is performed to form a film on the substrate 5.

That is, the evaporation source Y₂O₃ in the crucible 12 and the evaporation source YF₃ in the crucible 13 are evaporated in parallel while irradiating with ions (ion beams) from the ion gun 14.

The evaporation source melts and evaporates by being irradiated with electron beams (not illustrated).

In this way, the evaporated evaporation source adheres to the deposition surface of the substrate 5 (or the surface of the base layer or the surface of the stress-relaxation layer when the base layer or the stress-relaxation layer is present), and an yttrium-based protective film containing yttrium oxyfluoride is formed.

The ions irradiated from the ion gun 14 conform to the case where the yttrium-based protective film containing yttrium oxide (Y₂O₃) is formed.

### <<Deposition Rate>>

The ratio of deposition rate (Y₂O₃/YF₃) of the deposition rate (unit: nm/min) of the evaporation source Y₂O₃ to the deposition rate (unit: nm/min) of the evaporation source YF₃ is preferably 1/9.5 or more, more preferably 1/8.0 or more, still more preferably 1/6.0 or more, and particularly preferably 1/4.5 or more.

On the other hand, the ratio of deposition rate (Y₂O₃/YF₃) is preferably 1/1.1 or less, more preferably 1/1.3 or less, still more preferably 1/1.8 or less, and particularly preferably 1/2.5 or less.

The total rate of the deposition rate of the evaporation source Y₂O₃ and the film formation rate of the evaporation source YF₃ is preferably 5 nm/min or more, more preferably 8 nm/min or more, and still more preferably 10 nm/min or more. On the other hand, the total rate is preferably 50 nm/min or less, more preferably 35 nm/min or less, and still more preferably 20 nm/min or less.

### <<Internal Pressure of Chamber, Temperature of Substrate, Conditions of Ion Irradiation, and Ar/O Ratio>>

The internal pressure of the chamber, the temperature of the substrate, the conditions of ion irradiation, and the Ar/O ratio when forming the yttrium-based protective film containing yttrium oxyfluoride conform to a case where the yttrium-based protective film containing yttrium oxide (Y₂O₃) is formed.

### <Formation of Base Layer>

Before the yttrium-based protective film is formed, the above-described base layer (for example, the base layer 1, the base layer 2, and the base layer 3) is preferably formed on the deposition surface of the substrate 5.

Similarly to the yttrium-based protective film, the base layer is formed by ion assisted deposition.

For example, when a base layer made of Al₂O₃ is formed, Al₂O₃ is charged in one or both of the crucible 12 and the crucible 13 as an evaporation source, and the evaporation source is evaporated while irradiating with ions (ion beams) from the ion gun 14 to adhere the evaporation source to the deposition surface of the substrate 5.

Conditions for forming the base layer conform to the conditions for forming the yttrium-based protective film.

The substrate may contain water of crystallization.

For example, when the temperature of a substrate made of aluminum oxide (Al₂O₃) is increased from room temperature, the generation of water of crystallization due to a hydrate which is a low-temperature stable phase of aluminum oxide (for example, boehmite y alumina) is observed at a temperature around 52° C.

When moisture caused by the water of crystallization of the substrate is contained in the formed yttrium-based protective film, the number of hydrogen atoms in the yttrium-based protective film tends to increase.

Therefore, before the evaporation source Y₂O₃ adheres to the deposition surface of the substrate (that is, before the yttrium-based protective film is formed), the base layer and/or the stress-relaxation layer are/is formed on the deposition surface of the substrate.

Accordingly, at least the deposition surface of the substrate is covered, and therefore, water of crystallization of the substrate is less likely to be contained in the formed yttrium-based protective film, and further, the number of hydrogen atoms in the yttrium-based protective film is reduced, which is preferable.

### <Formation of Stress-Relaxation Layer>

The stress-relaxation layers (for example, the stress-relaxation layer 8 and the stress-relaxation layer 9) are formed by performing ion assisted deposition, similarly to the yttrium-based protective film.

For example, when a stress-relaxation layer containing Y₂O₃ and SiO₂ is formed, Y₂O₃ is charged in the crucible 12 as an evaporation source, SiO₂ is charged in the crucible 13 as an evaporation source, and the evaporation source is evaporated while irradiating with ions (ion beams) from the ion gun 14 to adhere the evaporation source to the deposition surface of the substrate 5.

When a stress-relaxation layer containing three or more kinds of oxides is formed, another crucible and a quartz crystal film thickness monitor (neither of which is illustrated) are then disposed in the chamber 11 to form a stress-relaxation layer.

For example, when a stress-relaxation layer containing Y₂O₃, SiO₂, and Al₂O₃ is formed, Y₂O₃ is charged in the crucible 12 as an evaporation source, SiO₂ is charged in the crucible 13 as an evaporation source, Al₂O₃ is charged in another crucible (not illustrated) as an evaporation source, and the evaporation source is evaporated while irradiating with ions (ion beams) from the ion gun 14 to adhere the evaporation source to the deposition surface of the substrate 5.

In addition, conditions for forming the stress-relaxation layer conform to the conditions for forming the yttrium-based protective film.

### <Pre-Heating of Substrate>

For the reason that water of crystallization of the substrate is less likely to be contained in the yttrium-based protective film, it is preferable to heat (preheat) the substrate at a high temperature before forming the yttrium-based protective film.

The preheating temperature is preferably 300° C. or higher, more preferably 400° C. or higher, still more preferably 450° C. or higher, and particularly preferably 500° C. or higher.

On the other hand, the preheating temperature is, for example, 800° C. or lower, preferably 750° C. or lower, and more preferably 700° C. or lower.

The preheating time is preferably 60 minutes or longer, more preferably 120 minutes or longer, still more preferably 240 minutes or longer, and particularly preferably 480 minutes or longer.

On the other hand, the preheating time is preferably 1200 minutes or shorter, more preferably 1000 minutes or shorter, still more preferably 800 minutes or shorter, and particularly preferably 600 minutes or shorter.

The preheating atmosphere is, for example, an air atmosphere.

### EXAMPLES

Hereinafter, the present invention is specifically described with reference to Examples. However, the present invention is not limited to Examples described below.

Hereinafter, Examples 1 to 24 are Inventive Examples, and Examples 25 and 26 are Comparative Examples.

### Examples 1 to 26

Members each including an yttrium-based protective film were produced under the conditions shown in the following Tables 1 to 3 using the apparatus described based on FIG. 5.

As the substrate, a circular substrate (thickness: 10 mm) having a deposition surface with a diameter (maximum length) of a value shown in Tables 1 to 3 below was used.

The substrate was preheated in an air atmosphere while being held by a holder in a chamber. The preheating temperature was 550° C., and the preheating time was 600 minutes.

Next, under the production conditions shown in the following Tables 1 to 3, a base layer, a stress-relaxation layer, and an yttrium-based protective film shown in the following Tables 1 to 3 were formed in this order on a deposition surface of a substrate using the LAD method.

When the base layer and/or the stress-relaxation layer were/was not formed, “-” was indicated in the corresponding column in the following Tables 1 to 3.

When forming the yttrium-based protective film, argon (Ar) ions and oxygen (O) ions were irradiated from an ion gun toward the substrate at Ar/O ratios shown in the following Tables 1 to 3.

When forming the base layer and/or the stress-relaxation layer, only oxygen (O) ions were irradiated from an ion gun.

As production conditions not indicated in the following Tables 1 to 3, the distance between the ion gun and the substrate was 1100 mm, and the ion beam current value was 2000 mA.

The compositions of the base layer, the stress-relaxation layer, and the yttrium-based protective film are shown in the following Tables 1 to 3.

Regarding the base layer and the stress-relaxation layer, for example, “30Y₂O₃÷70SiO₂” means that the content of Y₂O₃ is 30 mol %, and the content of SiO₂ is 70 mol %.

In the case where the yttrium-based protective film containing yttrium oxides was formed, “Y₂O₃” is indicated as the composition in the following Tables 1 to 3.

In the case where the yttrium-based protective film containing yttrium oxyfluorides was formed, the composition obtained from the content of each element (Y, O, F, etc.) is indicated as the composition in the following Tables 1 to 3.

The obtained member was subjected to the XRD measurement. When no peaks other than those of the components (yttrium oxide or yttrium oxyfluoride) of the yttrium-based protective film were observed, it was determined that the stress-relaxation layer was an amorphous layer, and “amorphous” was indicated in the column of “State” of “Stress-relaxation layer” in the following Table 3. On the other hand, when the peaks were observed, it was determined that the stress-relaxation layer contained a crystal, and “crystal” was indicated.

In addition, for the base layer, the stress-relaxation layer, and the yttrium-based protective film, the items (content of Ar and the like) shown in the following Tables 1 to 3 were obtained by the above-described method. Results are shown in the following Tables 1 to 3. The compressive stress is indicated by a negative numerical value.

### <Etching Amount>

The yttrium-based protective film of each example was subjected to ion etching to evaluate plasma resistance thereof.

Specifically, first, a surface of 10 mm×5 mm in the yttrium-based protective film was mirror-finished, and a part of the mirror-finished surface (referred to as a “test surface”) was masked with Kapton tape.

Next, using a CCP type plasma etching apparatus, plasma was generated by discharging in a gas under conditions of a pressure of 10 Pa and an RF power of 600 W, and a test (exposure test) of exposing the test surface to the generated plasma was performed.

More specifically, discharge (generation of plasma) was performed using CF₄ gas (flow rate: 100 sccm) and O₂ gas (flow rate: 100 sccm), and ions of CF₄ were generated in the plasma.

The discharge (generation of plasma) for 15 minutes was repeated 10 times, and an exposure test for a total of 150 minutes was performed. Thus, the non-masked portion of the test surface was etched.

Thereafter, the etching amount was determined by measuring a difference between the masked portion and the non-masked portion of the test surface by using a stylus surface profiler (Dectak 150, manufactured by ULVAC, Inc.). Results are shown in the following Tables 1 to 3.

As the etching amount (unit: nm) is smaller, plasma resistance can be evaluated to be excellent.

TABLE 1

| | | | Example 1 | Example 2 | Example 3 | Example 4 | Example 5 |
|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² |
| conditions | Substrate temperature [° C.] | | 400 | 400 | 400 | 400 | 400 |
| | Y₂O₃ | Evaporation source | 3.42 | 3.42 | 3.42 | 3.42 | 3.42 |
| | YF₃ | deposition rate | 0 | 0 | 0 | 0 | 0 |
| | | [nm/min] | | | | | |
| | Ar/O Ratio | | 3/50 | 6/50 | 8/50 | 22/50 | 6/50 |
| | Ion beam current density | | 80 | 80 | 80 | 80 | 80 |
| | [μA/cm²] | | | | | | |
| Substrate | Material | | Al₂O₃ | Al₂O₃ | Al₂O₃ | Al₂O₃ | Quartz |
| | Deposition | Ra [μm] | 0.02 | 0.02 | 0.02 | 0.02 | 0.02 |
| | surface | Area [cm²] | 314.2 | 314.2 | 314.2 | 314.2 | 314.2 |
| | | Maximum length [mm] | 200 | 200 | 200 | 200 | 200 |
| Base layer | 1 | Composition | — | — | — | — | — |
| | | Thickness [μm] | — | — | — | — | — |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | — | — | — | — | — |
| relaxation | | Thickness [μm] | — | — | — | — | — |
| layer | 2 | Composition | — | — | — | — | — |
| | | Thickness [μm] | — | — | — | — | — |

| | | | | | | |
|---|---|---|---|---|---|---|
| | State | Amorphous | Amorphous | Amorphous | Amorphous | Amorphous |
| Yttrium- | Composition | Y₂O₃ | Y₂O₃ | Y₂O₃ | Y₂O₃ | Y₂O₃ |
| based | O/Y Ratio | 1.20 | 1.16 | 1.13 | 1.26 | 1.16 |
| protective | Ar Content [atom %] | 0.23 | 0.50 | 0.91 | 1.13 | 0.51 |
| film | Number of hydrogen atoms | 1.9 | 1.8 | 1.8 | 1.9 | 1.8 |
| | [×10²¹ atoms/cm³] | | | | | |
| | Vickers hardness [HV] | 1262 | 1388 | 1412 | 1345 | 1334 |
| | Porosity [volume %] | 0.11 | 0 | 0 | 0.12 | 0 |
| | Crystallite size [nm] | 12.1 | 11.2 | 10.8 | 13.2 | 10.8 |
| | Degree of orientation [%] | 90.5 | 93.2 | 93.4 | 92.7 | 93.6 |
| | Peak intensity ratio [%] | — | — | — | — | — |
| | Thickness [μm] | 10.0 | 10.0 | 10.0 | 10.0 | 10.0 |
| | Compressive stress [MPa] | −1266 | −1247 | −1233 | −1266 | −1229 |
| | Average value of adhesion | 5.5 | 5.3 | 5.1 | 4.1 | 4.8 |
| | strength [N] | | | | | |
| | Standard deviation of adhesion | 0.4 | 0.3 | 0.2 | 0.5 | 0.3 |
| | strength [N] | | | | | |
| | Etching amount [nm] | 82 | 75 | 70 | 84 | 71 |

| | | | Example 6 | Example 7 | Example 8 | Example 9 |
|---|---|---|---|---|---|---|
| Production | Internal pressure of chamber [Pa] | | 1 × 10⁻² | 1 × 10⁻² | 1 × 10⁻² | 1 × 10⁻² |
| conditions | Substrate temperature [° C.] | | 400 | 400 | 400 | 400 |
| | Y₂O₃ | Evaporation | 3.42 | 3.42 | 3.42 | 3.42 |
| | YF₃ | source deposition | 0 | 0 | 0 | 0 |
| | | rate [nm/min] | | | | |
| | Ar/O Ratio | | 6/50 | 6/50 | 6/50 | 6/50 |
| | Ion beam current density | | 80 | 80 | 80 | 80 |
| | [μA/cm²] | | | | | |
| Substrate | Material | | Al₂O₃ | Quartz | Quartz | Quartz |
| | Deposition | Ra [μm] | 0.02 | 0.02 | 0.02 | 0.02 |
| | surface | Area [cm²] | 314.2 | 314.2 | 314.2 | 314.2 |
| | | Maximum length [mm] | 200 | 200 | 200 | 200 |
| Base layer | 1 | Composition | SiO₂ | SiO₂ | SiO₂ | SiO₂ |
| | | Thickness [μm] | 0.5 | 0.5 | 0.5 | 0.5 |
| | 2 | Composition | — | — | Al₂O₃ | 20Al₂O₃ + |
| | | | | | | 80SiO₂ |
| | | Thickness [μm] | — | — | 1 | 1 |
| | 3 | Composition | — | — | — | Al₂O₃ |
| | | Thickness [μm] | — | — | — | 1 |
| Stress- | 1 | Composition | — | 30Y₂O₃ + | 30Y₂O₃ + | 30Y₂O₃ + |
| relaxation | | | | 70SiO₂ | 70SiO₂ | 70SiO₂ |
| layer | | Thickness [μm] | — | 1.1 | 1.1 | 1.1 |
| | 2 | Composition | — | — | — | — |
| | | Thickness [μm] | — | — | — | — |

| | | | | | |
|---|---|---|---|---|---|
| | State | Amorphous | Amorphous | Amorphous | Amorphous |
| Yttrium- | Composition | Y₂O₃ | Y₂O₃ | Y₂O₃ | Y₂O₃ |
| based | O/Y Ratio | 1.17 | 1.16 | 1.17 | 1.16 |
| protective | Ar Content [atom %] | 0.50 | 0.51 | 0.50 | 0.50 |
| film | Number of hydrogen atoms | 1.8 | 1.8 | 2.2 | 2.1 |
| | [×10²¹ atoms/cm³] | | | | |
| | Vickers hardness [HV] | 1378 | 1328 | 1316 | 1302 |
| | Porosity [volume %] | 0 | 0 | 0 | 0 |
| | Crystallite size [nm] | 11.3 | 10.9 | 11.6 | 11.5 |
| | Degree of orientation [%] | 93.4 | 93.8 | 93.1 | 92.7 |
| | Peak intensity ratio [%] | — | — | — | — |
| | Thickness [μm] | 10.0 | 10.0 | 10.0 | 10.0 |
| | Compressive stress [MPa] | −1233 | −1237 | −1222 | −1227 |
| | Average value of adhesion | 5.5 | 4.9 | 5.4 | 5.4 |
| | strength [N] | | | | |
| | Standard deviation of | 0.3 | 0.3 | 0.3 | 0.2 |
| | adhesion strength [N] | | | | |
| | Etching amount [nm] | 77 | 72 | 74 | 77 |

TABLE 2

| | | | Example 10 | Example 11 | Example 12 | Example 13 | Example 14 |
|---|---|---|---|---|---|---|---|
| Production | Internal pressure of | | 1 × 10⁻² | 1 × 10⁻² | 1 × 10⁻² | 1 × 10⁻² | 1 × 10⁻² |
| conditions | chamber [Pa] | | | | | | |
| | Substrate temperature [° C.] | | 400 | 400 | 400 | 320 | 320 |
| | Y₂O₃ | Evaporation | 3.42 | 3.42 | 3.42 | 3.42 | 3.42 |
| | YF₃ | source | 0 | 0 | 0 | 0 | 0 |
| | | deposition rate | | | | | |
| | | [nm/min] | | | | | |
| | Ar/O Ratio | | 6/50 | 6/50 | 6/50 | 6/50 | 6/50 |
| | Ion beam current density | | 80 | 80 | 80 | 80 | 80 |
| | [μA/cm²] | | | | | | |
| Substrate | Material | | Al₂O₃ | Al₂O₃ | Al₂O₃ | Al₂O₃ | Al₂O₃ |
| | Deposition | Ra [μm] | 0.02 | 0.02 | 0.02 | 0.05 | 0.11 |
| | surface | Area [cm²] | 314.2 | 314.2 | 314.2 | 314.2 | 314.2 |
| | | Maximum length | 200 | 200 | 200 | 200 | 200 |
| | | [mm] | | | | | |
| Base layer | 1 | Composition | — | — | — | SiO₂ | SiO₂ |
| | | Thickness [μm] | — | — | — | 0.5 | 0.5 |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | — | — | — | 30Y₂O₃ + | 30Y₂O₃ + |
| relaxation | | | | | | 70SiO₂ | 70SiO₂ |
| layer | | Thickness [μm] | — | — | — | 1.1 | 1.1 |
| | 2 | Composition | — | — | — | — | — |
| | | Thickness [μm] | — | — | — | — | — |

| | | | | | | |
|---|---|---|---|---|---|---|
| | State | Amorphous | Amorphous | Amorphous | Amorphous | Amorphous |
| Yttrium- | Composition | Y₂O₃ | Y₂O₃ | Y₂O₃ | Y₂O₃ | Y₂O₃ |
| based | O/Y Ratio | 1.16 | 1.16 | 1.15 | 1.16 | 1.16 |
| protective | Ar Content [atom %] | 0.52 | 0.49 | 0.51 | 0.50 | 0.50 |
| film | Number of hydrogen atoms | 1.8 | 1.8 | 1.8 | 2.0 | 1.9 |
| | [×10²¹ atoms/cm³] | | | | | |
| | Vickers hardness [HV] | 1357 | 1339 | 1307 | 1345 | 1322 |
| | Porosity [volume %] | 0 | 0 | 0 | 0.11 | 0.19 |
| | Crystallite size [nm] | 11.2 | 11.1 | 10.7 | 9.8 | 9.5 |
| | Degree of orientation [%] | 93.2 | 92.7 | 93.4 | 91.9 | 90.7 |
| | Peak intensity ratio [%] | — | — | — | — | — |
| | Thickness [μm] | 5.0 | 3.0 | 1.0 | 10.0 | 10.0 |
| | Compressive stress [MPa] | −1227 | −1218 | −1220 | −1222 | −1189 |
| | Average value of adhesion | 5.2 | 4.9 | 4.8 | 4.7 | 4.4 |
| | strength [N] | | | | | |
| | Standard deviation of | 0.2 | 0.3 | 0.4 | 0.4 | 0.5 |
| | adhesion strength [N] | | | | | |
| | Etching amount [nm] | 74 | 77 | 76 | 74 | 79 |

| | | | Example 15 | Example 16 | Example 17 | Example 18 |
|---|---|---|---|---|---|---|
| Production | Internal pressure of | | 1 × 10⁻² | 1 × 10⁻² | 1 × 10⁻² | 1 × 10⁻² |
| conditions | chamber [Pa] | | | | | |
| | Substrate temperature [° C.] | | 320 | 320 | 320 | 320 |
| | Y₂O₃ | Evaporation | 3.42 | 3.42 | 3.42 | 3.42 |
| | YF₃ | source | 0 | 0 | 0 | 0 |
| | | deposition rate | | | | |
| | | [nm/min] | | | | |
| | Ar/O Ratio | | 6/50 | 6/50 | 6/50 | 6/50 |
| | Ion beam current density | | 80 | 80 | 80 | 80 |
| | [μA/cm²] | | | | | |
| Substrate | Material | | Al₂O₃ | Glass | Al | Al |
| | Deposition | Ra [μm] | 0.32 | 0.02 | 0.02 | 0.02 |
| | surface | Area [cm²] | 314.2 | 314.2 | 314.2 | 314.2 |
| | | Maximum length | 200 | 200 | 200 | 200 |
| | | [mm] | | | | |
| Base layer | 1 | Composition | SiO₂ | SiO₂ | Al₂O₃ | Alumite |
| | | Thickness [μm] | 0.5 | 0.5 | 1 | 1 |
| | 2 | Composition | — | — | — | — |
| | | Thickness [μm] | — | — | — | — |
| | 3 | Composition | — | — | — | — |
| | | Thickness [μm] | — | — | — | — |
| Stress- | 1 | Composition | 30Y₂O₃ + | 30Y₂O₃ + | 20Y₂O₃ + | 20Y₂O₃ + |
| relaxation | | | 70SiO₂ | 70SiO₂ | 80Al₂O₃ | 80Al₂O₃ |
| layer | | Thickness [μm] | 1.1 | 1.1 | 1.1 | 1.1 |
| | 2 | Composition | — | — | — | — |
| | | Thickness [μm] | — | — | — | — |

| | | | | | |
|---|---|---|---|---|---|
| | State | Amorphous | Amorphous | Amorphous | Amorphous |
| Yttrium- | Composition | Y₂O₃ | Y₂O₃ | Y₂O₃ | Y₂O₃ |
| based | O/Y Ratio | 1.15 | 1.16 | 1.16 | 1.18 |
| protective | Ar Content [atom %] | 0.50 | 0.50 | 0.51 | 0.50 |
| film | Number of hydrogen atoms | 1.9 | 1.5 | 1.4 | 1.9 |
| | [×10²¹ atoms/cm³] | | | | |
| | Vickers hardness [HV] | 1275 | 1028 | 980 | 1176 |
| | Porosity [volume %] | 0.32 | 0 | 0 | 0.28 |
| | Crystallite size [nm] | 9.6 | 9.5 | 9.9 | 10.1 |
| | Degree of orientation [%] | 89.2 | 94.2 | 90.4 | 91.9 |
| | Peak intensity ratio [%] | — | — | — | — |
| | Thickness [μm] | 10.0 | 1.0 | 1.0 | 1.0 |
| | Compressive stress [MPa] | −1120 | −834 | −1037 | −1098 |
| | Average value of adhesion | 4.1 | 4.8 | 4.7 | 5.0 |
| | strength [N] | | | | |
| | Standard deviation of | 0.6 | 0.5 | 0.4 | 0.3 |
| | adhesion strength [N] | | | | |
| | Etching amount [nm] | 84 | 84 | 98 | 74 |

TABLE 3

| | | | Example 19 | Example 20 | Example 21 | Example 22 |
|---|---|---|---|---|---|---|
| Production | Internal pressure of | | 1 × 10⁻² | 1 × 10⁻² | 1 × 10⁻² | 1 × 10⁻² |
| conditions | chamber [Pa] | | | | | |
| | Substrate temperature [° C.] | | 320 | 320 | 400 | 400 |
| | Y₂O₃ | Evaporation source | 3.42 | 3.42 | 3.42 | 3.42 |
| | YF₃ | deposition rate | 0 | 0 | 0 | 0 |
| | | [nm/min] | | | | |
| | Ar/O Ratio | | 6/50 | 6/50 | 6/50 | 6/50 |
| | Ion beam current density | | 80 | 80 | 80 | 80 |
| | [μA/cm²] | | | | | |
| Substrate | Material | | AlN | Cordierite | Al₂O₃ | Quartz |
| | Deposition | Ra [μm] | 0.02 | 0.02 | 0.02 | 0.02 |
| | surface | Area [cm²] | 314.2 | 314.2 | 9503.0 | 9503.0 |
| | | Maximum length [mm] | 200 | 200 | 200 | 200 |
| Base layer | 1 | Composition | Al₂O₃ | Al₂O₃ | — | — |
| | | Thickness [μm] | 1 | 1 | — | — |
| | 2 | Composition | — | — | — | — |
| | | Thickness [μm] | — | — | — | — |
| | 3 | Composition | — | — | — | — |
| | | Thickness [μm] | — | — | — | — |
| Stress- | 1 | Composition | 30Y₂O₃ + | 30Y₂O₃ + | — | — |
| relaxation | | | 70SiO₂ | 70SiO₂ | | |
| layer | | Thickness [μm] | 1.1 | 1.1 | — | — |
| | 2 | Composition | — | — | — | — |
| | | Thickness [μm] | — | — | — | — |
| | State | | Amorphous | Amorphous | Amorphous | Amorphous |
| Yttrium- | Composition | | Y₂O₃ | Y₂O₃ | Y₂O₃ | Y₂O₃ |
| based | O/Y Ratio | | 1.17 | 1.16 | 1.17 | 1.16 |
| protective | Ar Content [atom %] | | 0.51 | 0.50 | 0.51 | 0.52 |
| film | Number of hydrogen atoms | | 2.1 | 1.9 | 1.9 | 1.7 |
| | [×10²¹ atoms/cm³] | | | | | |
| | Vickers hardness [HV] | | 1248 | 1319 | 1340 | 1312 |
| | Porosity [volume %] | | 0 | 0 | 0 | 0 |
| | Crystallite size [nm] | | 10.4 | 10.7 | 12.1 | 11.3 |
| | Degree of orientation [%] | | 91.1 | 92.3 | 93.1 | 92.8 |
| | Peak intensity ratio [%] | | — | — | — | — |
| | Thickness [μm] | | 1.0 | 1.0 | 10.0 | 10.0 |
| | Compressive stress [MPa] | | −1103 | −1225 | −1246 | −1276 |
| | Average value of adhesion | | 5.2 | 5.1 | 5.2 | 5.0 |
| | strength [N] | | | | | |
| | Standard deviation of adhesion | | 0.2 | 0.3 | 0.2 | 0.3 |
| | strength [N] | | | | | |
| | Etching amount [nm] | | 71 | 74 | 77 | 79 |
| | | | Example 23 | Example 24 | Example 25 | Example 26 |
| Production | Internal pressure of | | 1 × 10⁻² | 1 × 10⁻² | 1 × 10⁻² | 1 × 10⁻² |
| conditions | chamber [Pa] | | | | | |
| | Substrate temperature [° C.] | | 270 | 270 | 400 | 400 |
| | Y₂O₃ | Evaporation source | 1.92 | 6.78 | 3.42 | 3.42 |
| | YF₃ | deposition rate | 13.36 | 8.76 | 0 | 0 |
| | | [nm/min] | | | | |
| | Ar/O Ratio | | 6/50 | 6/50 | 0/50 | 2/50 |
| | Ion beam current density | | 96 | 96 | 80 | 80 |
| | [μA/cm²] | | | | | |
| Substrate | Material | | Al₂O₃ | Quartz | Al₂O₃ | Al₂O₃ |
| | Deposition | Ra [μm] | 0.03 | 0.03 | 0.02 | 0.02 |
| | surface | Area [cm²] | 314.2 | 314.2 | 314.2 | 314.2 |
| | | Maximum length [mm] | 200 | 200 | 200 | 200 |
| Base layer | 1 | Composition | SiO₂ | SiO₂ | — | — |
| | | Thickness [μm] | 0.5 | 0.5 | — | — |
| | 2 | Composition | — | — | — | — |
| | | Thickness [μm] | — | — | — | — |
| | 3 | Composition | — | — | — | — |
| | | Thickness [μm] | — | — | — | — |
| Stress- | 1 | Composition | 30Y₂O₃ + | 30Y₂O₃ + | — | — |
| relaxation | | | 70SiO₂ | 70SiO₂ | | |
| layer | | Thickness [μm] | 1.1 | 1.1 | — | — |
| | 2 | Composition | — | — | — | — |
| | | Thickness [μm] | — | — | — | — |

| | | | | | |
|---|---|---|---|---|---|
| | State | Amorphous | Amorphous | Amorphous | Amorphous |
| Yttrium- | Composition | Y₅O_{4.3}F_{9.6} | Y₅O_{4.3}F_{8.7} | Y₂O₃ | Y₂O₃ |
| based | O/Y Ratio | 0.86 | 0.86 | 1.41 | 1.41 |
| protective | Ar Content [atom %] | 0.23 | 0.25 | 0.00 | 0.09 |
| film | Number of hydrogen atoms | 1.7 | 1.8 | 1.8 | 1.8 |
| | [×10²¹ atoms/cm³] | | | | |
| | Vickers hardness [HV] | 1002 | 1073 | 974 | 1012 |
| | Porosity [volume %] | 0 | 0 | 0 | 0 |
| | Crystallite size [nm] | 15.9 | 9.7 | 9.8 | 10.3 |
| | Degree of orientation [%] | — | — | 89.7 | 91.1 |
| | Peak intensity ratio [%] | 95.1 | 97.7 | — | — |
| | Thickness [μm] | 10.0 | 10.0 | 10.0 | 10.0 |
| | Compressive stress [MPa] | −802 | −915 | −889 | −1012 |
| | Average value of adhesion | 5.1 | 4.7 | 10.4 | 8.9 |
| | strength [N] | | | | |
| | Standard deviation of adhesion | 0.3 | 0.3 | 2.4 | 0.9 |
| | strength [N] | | | | |
| | Etching amount [nm] | 98 | 77 | 91 | 85 |

### <Conclusion of Evaluation Results>

As shown in Tables 1 to 3, it was found that Examples 1 to 24 had a smaller value of the standard deviation of the adhesion strength of the yttrium-based protective film and a smaller variation in the adhesion strength of the yttrium-based protective film than Examples 25 and 26.

Although the present invention has been described in detail with reference to specific embodiments, it is apparent to those skilled in the art that various changes and modifications can be made without departing from the spirit and scope of the present invention. The present application is based on a Japanese Patent Application (Japanese Patent Application No. 2023-183998) filed on Oct. 26, 2023, the content of which is incorporated herein by reference.

### REFERENCE SIGNS LIST

1, 2, 3: base layer
4: yttrium-based protective film
5: substrate
6: member
7: deposition surface
7a: first deposition surface
7b: second deposition surface
8, 9: stress-relaxation layer
11: chamber
12, 13: crucible
14: ion gun
15: heater
16: supporting shaft
17: holder
18, 19: quartz crystal film thickness monitor

What is claimed is:

1. An yttrium-based protective film comprising 0.10 atom % to 3.00 atom % of argon.

2. The yttrium-based protective film according to claim 1, having a porosity of less than 0.5 volume %.

3. The yttrium-based protective film according to claim 1, having a Vickers hardness of 1000 HV or more.

4. The yttrium-based protective film according to claim 1, having a Vickers hardness of 1300 HV or more.

5. The yttrium-based protective film according to claim 1, having a thickness of 0.05 μm or more and 15.0 μm or less.

6. The yttrium-based protective film according to claim 1, having a crystallite size of 6 nm or more and 40 nm or less.

7. The yttrium-based protective film according to claim 1, comprising 5 atom % or more of yttrium.

8. The yttrium-based protective film according to claim 1, wherein an O/Y ratio, which is a ratio of an oxygen content to an yttrium content, is 1.10 or more and 1.40 or less,
wherein units of the oxygen content and the yttrium content are both atom %.

9. The yttrium-based protective film according to claim 1, comprising an yttrium oxide.

10. The yttrium-based protective film according to claim 9, wherein a degree of orientation of a (222) plane of Y₂O₃ is 50% or more.

11. The yttrium-based protective film according to claim 1, wherein a peak intensity ratio of Y₅O₄F₇ in an X-ray diffraction pattern is 60% or more.

12. The yttrium-based protective film according to claim 1, having the number of hydrogen atoms of 5.0×10²¹ atoms/cm³ or less.

13. The yttrium-based protective film according to claim 1, having a compressive stress of 100 MPa to 1700 MPa.

14. A member comprising a substrate and the yttrium-based protective film according to claim 1 in this order.

15. The member according to claim 14,
wherein the substrate is made of at least one selected from the group consisting of carbon, ceramic, and metal,
the ceramic is at least one selected from the group consisting of glass, quartz, aluminum oxide, aluminum nitride, cordierite, yttrium oxide, silicon carbide, Si-impregnated silicon carbide, silicon nitride, sialon, and aluminum oxynitride, and
the metal is at least one selected from the group consisting of aluminum and an alloy comprising aluminum.

16. The member according to claim 14, wherein the substrate is made of quartz or aluminum oxide.

17. The member according to claim 14, wherein a surface roughness of a deposition surface of the substrate is, in terms of an arithmetic average roughness Ra, 0.001 μm or more and less than 1.0 μm.

18. The member according to claim 14, comprising one or more base layers between the substrate and the yttrium-based protective film,
wherein the base layer comprises at least one oxide selected from the group consisting of Al₂O₃, SiO₂, Y₂O₃, MgO, ZrO₂, La₂O₃, Nd₂O₃, Yb₂O₃, Eu₂O₃, and Gd₂O₃.

19. The member according to claim 18, comprising two or more base layers,
wherein the oxides in the adjacent base layers are different from each other.

20. The member according to claim 14,
wherein a maximum length of a deposition surface of the substrate is 30 mm or more,
the substrate comprises, as the deposition surface, a first deposition surface defining the maximum length and a second deposition surface different from the first deposition surface,
an angle formed between the first deposition surface and the second deposition surface is 20° to 150°, and
a proportion of an area of the second deposition surface to the total area of the deposition surface is 60% or less.

21. The member according to claim 14, which is used in a plasma etching apparatus or a plasma CVD apparatus.

22. A method for producing the yttrium-based protective film according to claim 1, the method comprising evaporating an evaporation source and depositing the evaporation source onto a substrate while irradiating with ions of at least one element selected from the group consisting of oxygen, argon, neon, krypton, and xenon from an ion gun in a vacuum,
wherein Y₂O₃ or a combination of Y₂O₃ and YF₃ is used as the evaporation source.

23. The method for producing the yttrium-based protective film according to claim 22,
wherein argon ions and oxygen ions are irradiated from the ion gun toward the substrate, and
an Ar/O ratio, which is a ratio of an ion amount of argon to an ion amount of oxygen, is more than 2/50,
wherein a unit of the ion amount is W/m².

24. The method for producing an yttrium-based protective film according to claim 22, comprising heating the substrate at 300° C. or higher before depositing the evaporation source onto the substrate.
